(19) United States
(12) Patent Application Publication
(10) Pub. No.: US 2026/0081618 A1
(43) Pub. Date: Mar. 19, 2026

(54) METHOD FOR DATA COMPRESSION AND RELATED DEVICE

(71) Applicant: Huawei Technologies Co., Ltd., Shenzhen (CN)

(72) Inventors: Aleksei Valentinovich Romanovskii, Moscow (RU); Vitaliy Sergeevich Kharin, Moscow (RU); Ivan Stanislavovich Blekanov, Saint Petersburg (RU); Alexander Borisovich Stuchenkov, Saint Petersburg (RU)

(21) Appl. No.: 18/995,624

(22) PCT Filed: Aug. 2, 2022
(86) PCT No.: PCT/RU2022/000245

§ 371 Date: Jan. 16, 2025

(51) Int. Cl. H03M 7/30

(52) U.S. Cl. CPC H03M 7/3088; H03M 7/6011

(57) ABSTRACT

This application provides a method that includes: obtaining an input data block; and processing the input data block by selecting one of alternatives: delta-compressing one or more target data blocks with the input data block used as a compression dictionary, where each target data block is one of processed data blocks; delta-compressing or deduplicating the input data block by using one of processed blocks as a dictionary or as a reference block for deduplication; independently compressing the input data block; or passing the input data block uncompressed for further processing.

### CROSS-REFERENCE TO RELATED APPLICATIONS

This application is a National Stage of International Patent Application No. PCT/RU2022/000245, filed on Aug. 2, 2022, which is hereby incorporated by reference in its entirety.

### TECHNICAL FIELD

Embodiments of the present invention relate to the field of information technologies, and more specifically, to a method for data compression and a related device.

### BACKGROUND

Data similarity (resemblance) detection is widely used in data storage, data transmission over network, plagiarism detection, web search, etc. Similarity detection, when used in data storage and transmission devices, makes it possible to apply deduplication or delta-compression for similar data, thus further improve efficiency of these devices.

Selection of a similarity candidate to use as a dictionary in delta-compression is quite computationally expensive, in particular for applications where near-real time latencies are required. Thus, it is worth considering how to make selection of a dictionary in delta-compression less computationally expensive.

### SUMMARY

Embodiments of this application provide a method for data compression and a related device. The technical solution provides an alternated compression dictionary from an input data block and a processed data block, which could make selection of a dictionary in delta-compression less computationally expensive and may provide a smaller compression ratio as well as a lower delta-recursion depth. To some extent, the technical solution may also result in less power usage.

According to a first aspect, an embodiment of this application provides a method for data compression, including: obtaining an input data block; and processing the input data block according to one of the following methods: delta-compressing one or more target data blocks by using the input data block as a compression dictionary, where each target data block is one of processed data blocks; delta-compressing the input block by using one of processed data blocks as a compression dictionary; independently compressing the input data block; or passing the input data block further uncompressed.

When the input data block is delta-compressed by using one of processed data blocks as a compression dictionary, the input data block may be equal to the one processed data block, in such case, the input data block would be deduplicated by using the processed data block as a duplicate reference data block. It should be understood that such a case would also happen when delta-compressing one or more of the target data blocks by using the input data block as a compression dictionary.

The proposed compression method disclosed in this technical solution is an alternated option to take an input data block as a target block for delta-compression, which could result in a better compression ratio (CR), a lower compression recursion depth and lower power usage to some extent by using the input data block as a compression dictionary.

By means of the proposed compression method, a better compression method choice could be made when different aspects need to be considered in different application situations.

In a possible design, before processing the input data block according to one of the following methods, the method further includes: determining to use the input data block as the compression dictionary according to reference information to delta-compress the target data blocks, where the reference information is used to evaluate compression and/or decompression costs of the target data blocks by using the input data block as the compression dictionary; and incrementing a reference count of the input data block by a number of the target blocks.

Optionally, if using the input data block as the compression dictionary results in a better CR, then it is preferred to use the input data block as the compression dictionary, otherwise, it is preferred to delta-compress the input data block in respect to the dictionary selected from processed data blocks.

Optionally, if using the input data block as the compression dictionary results in a lower compression recursion depth, then it is preferred to use the input data block as the compression dictionary, otherwise, it is preferred to delta-compress the input data block in respect to the dictionary selected from processed data blocks.

Optionally, if using the input data block as the compression dictionary results in less CPU cycles or less power usage, then it is preferred to use the input data block as the compression dictionary, otherwise, it is preferred to delta-compress the input data block in respect to the dictionary selected from processed data blocks.

The proposed compression method disclosed in this technical solution introduces reference information at the time of determining whether to use the input data block as the compression dictionary to compress the processed data block. This compression method makes it clearer and easier to make that decision.

In a possible design, the reference information includes one or more of a compression ratio, CPU cycles spent for delta-compression and/or delta-decompression, latencies of compression and/or decompression due to delta-compression recursion depth.

The reference information could include one or more of a CR, a compression recursion depth and CPU cycles, which could reflect different aspects of a delta-compression result. Especially, taking the compression recursion depth into account equals to taking the balance between the CR, a throughput speed and a latency into consideration, which may be beneficial to user experience of an electronic device.

In a possible design, in case the target data blocks are delta-compressed, delta-compressing the one or more target data blocks by using the input data block as the compression dictionary includes: decompressing each of the target data blocks as a decompression result; compressing the decompression result by using the input data block as the compression dictionary; and incrementing a reference count of the input data block by 1.

In case the target data block is not delta-compressed, it may also be used for delta-compression without a delta-decompressing process. It should be mentioned that, the input data block used as a compression dictionary may be compressed or uncompressed.

No matter whether the target data blocks are compressed or uncompressed, they may be delta-compressed by using the input data block as a compression dictionary. Decompression of the target data block that has been delta-compressed makes it possible to cut off a relationship between the target data block and its previous dictionary which is one or more of the processed data blocks, so as to be helpful to delete the previous dictionary (if not used as a dictionary for delta-compression or deduplication of other blocks) and the previous compression result of the target data block. The proposed compression method disclosed in this technical solution has a positive effect on sparing of storage space.

In a possible design, the method further includes: decrementing a reference count of a previous compression dictionary, where the previous compression dictionary is used to compress the target data blocks, and the previous compression dictionary differs from the input data block.

In a possible design, the method further includes: deleting the previous compression dictionary if the reference count is 0.

Here, that the reference count of the previous compression dictionary is 0 means the previous compression dictionary is not used as a dictionary for delta-compression or deduplication of other blocks.

By deleting the previous compression dictionary of the target data block, the proposed compression method disclosed in this technical solution has a positive effect on sparing of storage space.

In a possible design, the method further includes: deleting a previous compression result of the each target data block, where the previous compression result is corresponding to the decompression result.

By deleting the previous compression result of the target data block, the proposed compression method disclosed in this technical solution has a positive effect on sparing of storage space.

In a possible design, the method further includes: checking if the target data blocks are delta-compressed.

Checking the target data block is helpful to determine whether the target data block needs decompression or not, which could have good benefit in decreasing the latency of delta-compression.

In a possible design, the method further includes: storing a similarity degree between each of the target data blocks and the input data block.

A similarity degree between the target data block and the input data block could be used to determine whether to use a future input data block as a dictionary or not, so the proposed compression method disclosed in this technical solution has a positive effect on the whole delta-compression efficiency, such as a CR, power usage, and a latency.

In a possible design, the method further includes: verifying that a similarity degree between each of the target data blocks and the input data block is within a threshold range.

Setting or predefining a threshold range of the similarity degree between the target data block and the input data block will expand application scenarios of the proposed compression method disclosed in this technical solution.

For explanations and beneficial effects of the technical solutions of the products provided below, reference may be made to the content of the relevant technical solutions in the first aspect above, which will not be repeated below.

According to a second aspect, provided is an electronic device, including: an obtaining module configured to obtain an input data block; a determining module configured to process the input data block according to one of the following methods: delta-compress one or more target data blocks by using the input data block as a compression dictionary, where each target data block is one of processed data blocks; delta-compress the input data block by using one of processed data block as a compression dictionary; independently compress the input data block; or pass the input data block further uncompressed.

In a possible design, the determining module is further configured to determine to use the input data block as the compression dictionary according to reference information to delta-compress the one or more target data blocks, where the reference information is used to evaluate compression and/or decompression costs of the target data blocks by using the input data block as the compression dictionary; and increment a reference count of the input data block by a number of the target blocks.

In a possible design, the reference information includes one or more of a compression ratio, CPU cycles spent for delta-compression and delta-decompression, latencies of compression and decompression due to delta-compression recursion depth.

In a possible design, in case the target data blocks are delta-compressed, the determining module is further configured to decompress each of the target data blocks as a decompression result; compress the decompression result by using the input data block as the compression dictionary, and increment a reference count of the input data block by 1.

In a possible design, the determining module is further configured to decrement a reference count of a previous compression dictionary, where the previous compression dictionary is used to compress the target data block and the previous compression dictionary differs from the input data block.

In a possible design, the determining module is further configured to delete the previous compression dictionary if the reference count is 0.

Here, that the reference count of the previous dictionary is 0 means the previous compression dictionary is not used as a dictionary for delta-compression or deduplication of other blocks.

In a possible design, the determining module is further configured to delete a previous compression result of the each target data block, the previous compression result is corresponding to the decompression result.

In a possible design, the determining module is further configured to check if the target data blocks are delta-compressed.

In a possible design, the determining module is further configured to store a similarity degree between each of the target data blocks and the input data block.

In a possible design, before determining to use the input data block as the compression dictionary according to reference information to delta-compress the target data blocks, the determining module is further configured to verify that a similarity degree between each of the target data blocks and the input data block is within a threshold range.

According to a third aspect, an electronic device is provided, including a processor and a memory. The processor is connected to the memory. The memory is configured to store instructions, the processor is configured to execute the instructions. When the processor executes the instructions stored in the memory, the processor is enabled to perform the method in the first aspect or any possible design of the first aspect.

According to a fourth aspect, an embodiment of this application provides a computer readable storage medium, including instructions. When the instructions are run on a computer, the computer is enabled to perform the method in the first aspect or any possible design of the first aspect.

According to a fifth aspect, a chip system is provided, where the chip system includes a memory and a processor, where the memory is configured to store a computer program, and the processor is configured to invoke the computer program from the memory and run the computer program, so that a server on which the chip is disposed performs the method in the first aspect or any possible design of the first aspect.

According to a sixth aspect, a computer program product is provided, where when the computer program product is run on an electronic device, the electronic device is enabled to perform the method in the first aspect or any possible design of the first aspect.

### BRIEF DESCRIPTION OF THE DRAWINGS

FIG. 1 shows a flowchart of an embodiment of a method for data compression.

FIG. 2 shows a flowchart of another embodiment of a method for data compression.

FIG. 3 shows a flowchart of yet another embodiment of a method for data compression.

FIG. 4 shows a schematic diagram for comparison between two different data compression methods.

FIG. 5 shows a schematic block diagram of an electronic device according to an embodiment of this application.

FIG. 6 shows a schematic block diagram of another electronic device according to an embodiment of this application.

### DETAILED DESCRIPTION OF ILLUSTRATIVE EMBODIMENTS

The following describes the technical solutions in this application with reference to the accompanying drawings.

In information theory, data compression, source coding, or bit-rate reduction is the process of encoding information by using fewer bits than the original representation. Any particular compression is either lossy or lossless. Lossless compression reduces bits by identifying and eliminating statistical redundancy. No information is lost in lossless compression. Lossy compression reduces bits by removing unnecessary or less important information. Typically, a device that performs data compression is referred to as an encoder, and one that performs the reversal of the process (decompression) is referred to as a decoder.

Compression is useful because it reduces resources required to store and transmit data. Computational resources are consumed in the compression and decompression processes. Data compression is subject to a space-time complexity trade-off. The design of data compression schemes involves trade-offs among various factors, including a degree of compression, an amount of distortion introduced (when using lossy data compression), and computational resources required to compress and decompress data.

Delta encoding is one kind of lossless compression method, which is a way of storing or transmitting data in the form of differences (deltas) between sequential data rather than complete files; and more generally, this is known as data differencing. Delta encoding is sometimes called delta compression, particularly in a case where archival histories of changes are required (e.g., in revision control software).

Data compression ratio or compression ratio (CR), also known as compression power, is a measurement of the relative reduction in size of data representation produced by a data compression algorithm. It is typically expressed as the division of uncompressed size by compressed size, and is given by:

$$CR = \frac{Uncompressed Size}{Compressed Size}$$

Recursion is a process of defining a problem (or a solution to a problem) in terms of (a simpler version of) itself. Compression recursion refers to recursion that happens during a compression process. As for delta-compression, for example, compression recursion happens in the following situation.

Data block is an input data block A (or an incoming data block), and data block B, data block C and data block D are three processed data blocks. While data block D is a dictionary for delta-compression of block C, delta C is a delta-compression result by using data block D as a dictionary, and the whole block C is also a dictionary for block B. In a case that delta B is a delta-compression result by using data block C as a dictionary, and the whole block B is also similar with the input data block A, if data block A is delta-compressed by using the whole block B as a dictionary, then a delta-recursion level of data block A is 3, and a delta-recursion level of data block B is 2. In this example of delta-decompressing block A, one needs first to delta-decompress block B. In turn, to delta-decompress block B, one needs to delta-decompress block C. This sequence represents recursion in delta-decompression of blocks A, B, and C.

However, in the above example, if the input data block A is used as a dictionary to compress delta of block B, the block A is separately compressed. In this case, a delta-recursion level of data block A is 0, and a delta-recursion level of data block B is 1. It should be understood that a lower recursion level means less CPU cycles for de-compression.

Delta-compression recursion depth could be used to express the count of delta-compression recursions that happens for the whole delta-compression process of one block.

However, once compression recursion happens, more CPU cycles are spent on decompression. So, compression recursion extends either compression process or decompression process. In another way, compression recursion has a negative effect on a latency of compression or decompression.

What can be concluded above is that, if compression recursion could be taken into account in delta-compression, CR or latency would be affected to some extent. But how to take compression recursion into account is a question.

It should be mentioned that in this disclosure, the term “input data block” equals to “input block”, and they should not be distinguished from each other. The same is true for terms “target data block” and “target block”, as well as terms “processed data blocks” and “processed blocks”. The target block is a block for delta-compression, it may be an input data block or a processed data block, and target data blocks may be more than one input data blocks or processed data blocks.

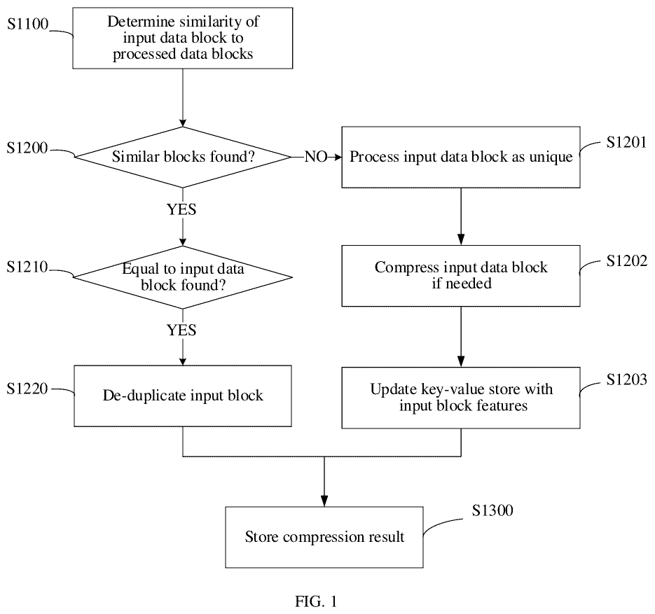

As shown in FIG. 1, one delta-compression method is provided by this disclosure. As depicted in FIG. 1, the method works by the following steps:
S1100, determining similarity of an input data block to processed data blocks.

Before S100, the input data block should be got or received or obtained by a block device, which may be an effect of any write operation to the block device. The block device could be an electronic device that is used to store/retrieve data blocks and can execute a compression process and/or a decompression process

In some possible embodiments, the input data block may be compressed before S1100. Here, the method of compressing the input data block before S100 may not be the same with delta-compression.

There are many similarity detection methods that could be used in S1100. Generally, similarity detection comes with collecting features of two blocks followed by comparing these collected features. In some possible embodiments, a key-value store or a hash-table could be used for selected similarity features (samples/chunks). In order to make it clear and easy to be understood, the following embodiments take a key-value store for example, which should not be construed as a limitation on this application. The following is one example for explaining how a similarity detection method works.

In one possible embodiment, similarity detection may be done by any method of chunking (sampling) and hashing. For example, an algorithm takes fixed size samples, for example, 16 bytes at the beginning, at offset inside of an incoming block, and at the end of a block. Hash is calculated for each sample. Hash is then used as a key for look-up in a key-value store. The key-value store contains key-value pairs, where a key is a hash for block samples of already processed blocks, and a value is a vector/tuple.

If the look-up by key (calculated for a sample of incoming block) returns one or more key-value pairs corresponding to the already processed blocks, it means respective samples of the already processed blocks may be equal to the sample of incoming block. To make approximate estimation more precise, some implementations may retrieve the already processed blocks and compare their respective samples with the sample of incoming block. If samples are equal after comparison, then two blocks are certainly similar. Number of bytes in equal samples could be used as another approximation of similarity.

In some embodiments, the input data block may be compressed or not compressed before applying any proper similarity detection method. Here, the method of compressing the input data block before applying any proper similarity detection method may not be the same with delta-compression.
S1200, determining whether similar blocks are found or not.

By using different similarity detection methods, different detecting results will be generated. While if the detecting results indicate or imply that there are similar blocks found, the method continues to S1210. Here the similar block may also be named as a target data block.
S1210, determining if blocks equal to the input data block are found.

In one possible embodiment, five different block features are collected respectively by performing hashing or sampling for an input data block and a target data block. Here, the target data block is one or more of the processed data blocks. And in S1200, there are two features matched for the input data block and the target data block, which meets the criterion of a similar block. In S1210, the last three features are further compared, and as a result, these three features are also matched. Consequently, the input data block is determined fuzzy equal to the target data block.

Optionally, if there is no data block found fuzzy equal to the input data block, a similarity degree of the input data block may be calculated. In some possible embodiments, if the similarity degree between any found block and the input data block is below a threshold, then the input data block is processed as unique.

The similarity degree in this application is a number of equal bytes in two blocks, and is detected by a delta-compression algorithm. When the delta-compression algorithm is provided with a dictionary block and other, target, block for delta-compression, the algorithm searches what substrings (“words”) from a dictionary are present (repeating) in that other block.

If no “words” from the dictionary are found in the other block, then delta-compression fails in this case, and the other block is considered as unique and processed. The more “words” from dictionary are found in the other block, the more efficient delta-compression of that other block is. In an extreme case where the other block is the same as (equal to) dictionary, the other block is considered as duplicate and metadata for the other block contains reference to a dictionary block and a “duplicate” tag.

Here metadata in general is some traits/characteristics of data. In particular, when storing data blocks in as a either compressed or uncompressed manner on a storage device, a similarity degree may also be stored in this special data structures, along with a stored data block address on storage media, a hash value calculated for stored data, etc. All these special data structures are called metadata.

In some possible embodiments, metadata of a delta-compressed block among other things could contain reference to (an address of) metadata describing a dictionary block that was used for delta-compression. The following is one example of expression of metadata.
<sample_offset_in_already_processed_block, address_of_already_processed_block, other_metadata_for_already_processed_block>.

In some possible embodiments, the similarity degree could be calculated by one or more of cosine similarity, Euclidean distance, edit distance, hamming distance, etc.

Here, distinction may be a substitute for “unique”, which means there is no data block among the processed data blocks that is similar with the input data block. It should be mentioned that definition of “similar with” may differ in different situations, and it is an approximate metric and may be predefined in a compression algorithm.
S1220, de-duplicating the input block.

In some embodiments, if any found similar block is fuzzy equal to the input block, then the input data block is de-duplicated, and as a result, the input data block is replaced by reference to the found fuzzy equal block. A reference count of the fuzzy equal block is incremented to reflect another found duplicate.

It should be mentioned that the expression “fuzzy equal” here is an approximate metric and may not reflect one data block is the same as another data block byte to byte. In some possible embodiments, it means a comparison result between one data block and another data block meets a criterion which may be predefined. In other words, the criterion of “fuzzy equal” may differ in different situations.

It could be understood that the full comparison between one data block and another data block byte by byte could result in more computation resources as well as lower power efficiency, so as to be meaningless in some conditions. So, a flexible criterion of “fuzzy equal” and “similar with” would have positive benefit on a compression or decompression process.

While if the detecting results indicate or imply that there is no similar block found, then the method goes to S1201.
S1201, processing the input data block as unique.

Here, distinction may be a substitute for “unique”, which means there is no data block among the processed data blocks that is similar with the input data block. It should be mentioned that definition of “similar with” may differ in different situations, and it is an approximate metric and may be predefined in a compression algorithm.

In some possible embodiments, the similarity degree could also be used to confirm that there is no data block when a similarity degree of any found data block is below a threshold.
S1202, compressing the input data block if needed.

Specifically, if the input data block has not been compressed, then it is compressed.

In one possible embodiment, the input data block was not compressed earlier, and its compression may be skipped due to throughput (CPU cost) requirements. In this case, the input data block would not be compressed. Here, the method of compressing the input data block may not be the same with delta-compression.

In another possible embodiment, in the course of similarity detection, the input data block may be determined as either a non-compressible block or a “pattern” block (for example, 8 bytes repeating through the block). In this case, the input data block would not be compressed.
S1203, updating a key-value store with input block features.

As described above, block features like a key-value store and a hash-table could be used for similarity detection. Here, updating the key-value store with the input data block features means adding features of the input data block to a block feature set. The block feature set also contains processed data block features. Features in the block feature set could be used for comparison with future input data block features.
S1300, storing a compression result.

The compression result could be expressed in different expressions, and the following expression is an example, which should not be construed as a limitation of this application.
[blockID3] string1 (matched with part of block3) string2

Here, blockID3 is used to indicate block3, and string1 and string2 are parts of a data block that could not be matched with any part of block3.

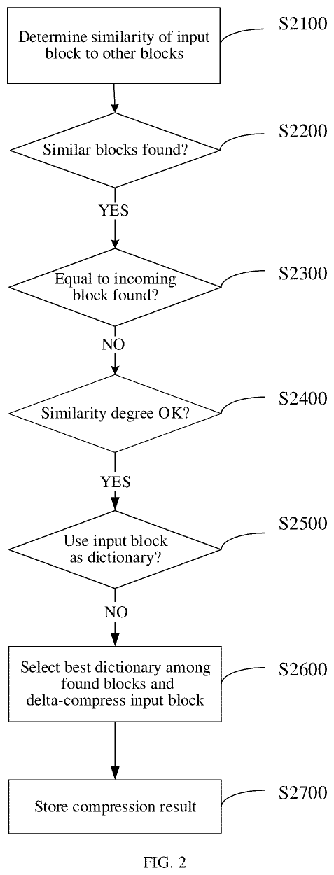

Another delta-compression method is provided by this disclosure, as shown in FIG. 2. This embodiment mainly emphasizes on how to determine whether to use an input data block as a compression dictionary or not. As depicted in FIG. 2, the method works by following steps:
S2100, determining similarity of an input data block to processed data blocks.

Specifically, what executed in S2100 is basically the same as that executed in S1100. In order to avoid redundancy, details here will not be repeated again and can refer to S1100.
S2200, determining whether similar blocks are found or not.

Specifically, what executed in S2200 is basically the same as that executed in S1200. In order to avoid redundancy, details here will not be repeated again and can refer to S1200.
S2300, determining if blocks equal to the input data block are found.

Specifically, what executed in S2300 is basically the same as that executed in S1210. In order to avoid redundancy, details here will not be repeated again and can refer to S1210.
S2400, optionally, determining a compression method according to a similarity degree.

The similarity degree here refers to a similarity degree between one or more processed data blocks and the input data block. The similarity degree is a total number of equal bytes in all repeating “words” found by a delta-compression algorithm. In other words, the similarity degree is a number of equal bytes in two data blocks. In some possible embodiments, the similarity degree is calculated by one or more of cosine similarity, Euclidean distance, edit distance, hamming distance, etc.

In some possible embodiments, if the similarity degree is below a predefined threshold, then it is preferred to process the input data block as unique.

In some other possible embodiments, if the similarity degree is above a predefined threshold, then it is preferred to determine whether to use the input data block as a dictionary. Namely, continue to S2500.
S2500, determining whether to use the input data block as a dictionary or not?

There is no definite criterion for this determination, but one or more following aspects could be taken into account when making this decision, for example, a compression ratio, a recursion depth, CPU cycles, etc. These criteria may be used either jointly or separately.

Generally, determining whether to use the input data block as the dictionary or not is a balance of a variety of aspects. In some possible embodiments, the CR is considered as the first priority aspect, and then in S2500, if using the input data block as the dictionary will result in a better CR, it is preferred to use the input data block as the dictionary. On the contrary, if using the input data block as the dictionary will result in a worse CR, it is preferred not to use the input data block as the dictionary. In one possible embodiment, if using the input data block as the dictionary will result in a worse CR, it is preferred to delta-compress the input data block in respect to the dictionary selected from the processed data blocks.

In some other possible embodiments, the recursion depth is considered as the first priority aspect, then in S2500, if using the input data block as the dictionary will result in a lower recursion depth, it is preferred to use the input data block as the dictionary. On the contrary, if using the input data block as the dictionary will result in a higher recursion depth, it is preferred not to use the input data block as the dictionary. In one possible embodiment, if using the input data block as the dictionary will result in a higher recursion depth, it is preferred to delta-compress the input data block in respect to the dictionary selected from the processed data blocks.

In some other possible embodiments, there is a threshold for the CR and the recursion depth respectively, then in S2500, if using the input data block as the dictionary will result in a better CR above threshold1 and a lower recursion depth below threshold2, it is preferred to use the input data block as the dictionary.

CPU cycles could be used to reflect power usage (like battery usage) in a delta-compression or delta-decompression process, and when CPU cycles are spared, battery usage will be lower. It could be understood that in different application situations or use cases, CPU cycles or battery usage is affected by different aspects.

In one possible embodiment, delta-compression is proceeded by a storage device in a Linux kernel (like zRAM). A lot of data blocks (or pages) are compressed but not many of them survive and are read. Here similarity detection, delta-compression and compression proper are on a critical path in terms of battery usage. The less cycles we spend on similarity detection, compression and delta-compression, the better battery usage is.

In another possible embodiment, delta-compression is invoked for a data base (DB) or the like by a traditional block device. A lot of data blocks are repeated, e.g., for single write, there may be 10+ reads. Here delta-decompression and decompression proper are on a critical path in terms of power usage. The less cycles we spend on delta-de-compression, the better power usage is. It means avoidance or decrease of compression recursion could result in efficient delta-compression. Here decompression proper means delta-decompression that differs from regular decompression or non-delta decompression.

In some possible embodiments, an approximate method could be used to test if use of the input data block as the dictionary to delta-compress or delta-re-compress found similar blocks will have good benefit. The following is an example.

Let P denote an incoming block, Q denote a found similar block that is delta-compressed in respect to a dictionary R. Let bytes_count_in_equal_samples (P, Q) denote a number of bytes in equal samples found in blocks P and Q using sampling and hashing as described in S100. Let sd_Q (R) is a similarity degree calculated between blocks Q and R previously during delta-compression of block Q.

Then if bytes_count_in_equal_samples (P, Q)>sd_Q (R), it could be concluded that delta-recompression of Q using P as a dictionary will result in a better CR. Then it is preferred to compress the block Q with the block P as a compression dictionary, otherwise, it is preferred to compress the block P with the block Q as a compression dictionary.

Uncontrolled recursion makes delta-compression and/or delta-de-compression expensive in terms of CPU cycles. Taking a recursion depth into consideration has positive benefits on compression or de-compression efficiency. When making decision on whether using the input data block as a compression dictionary, it is helpful to take compression recursion into consideration.

The recursion depth could be estimated by traversing metadata for found similar blocks. Here, metadata for a delta-compressed block among other things could contain reference to (an address of) metadata describing a dictionary block that was used for delta-compression. Specifically, the recursion depth could be estimated by counting the delta-recursion depth on the way when traversing metadata until reaching a dictionary block that was not delta-compressed.

By comparing the recursion depth estimated by using the input data block as the dictionary to compress the processed data block with the recursion depth estimated by using the processed data block as the dictionary to compress the input data block, if using the input data block as the dictionary will result in a lower compression recursion depth could be determined. If it could result in a lower compression recursion depth, then it is preferred to compress the processed block similar with the input data block by using the input data block as the dictionary, otherwise, it is preferred to compress the input data block by using the processed data block similar with the input data block.

Actually, recursion depth control considers overall balance between a CR, a throughput speed and a latency. Usually, a better CR is achieved at the cost of compression and de-compression throughput. The delta-compression recursion may increase a CR, and in turn decreases a speed of delta-compression and delta-de-compression and makes a latency worse.
S2600, selecting a dictionary among found data blocks and delta-compressing the input data block.

If decision of not using the input data block as the dictionary is made in S2500, then S2600 will be executed.
S2700, storing a compression result.

Specifically, a result of delta-compression is stored. The contents of delta-compression have been introduced in S1300. In order to avoid redundancy, details here will not be repeated again and can refer to S1300.

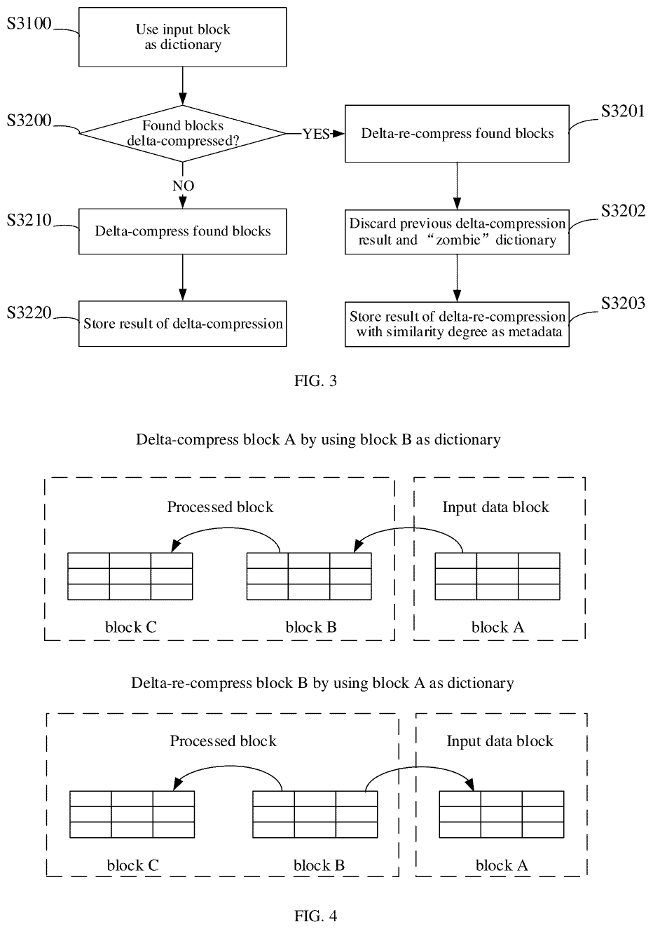

Another delta-compression method is provided by this disclosure, as shown in FIG. 3. This embodiment mainly emphasizes on how to use an input data block as a compression dictionary. As depicted in FIG. 3, the method works by the following steps:
S3100, determining to use an input data block as a dictionary.

There is no definite criterion for this determination, but one or more following aspects could be taken into account when making this decision, for example, compression ratio, recursion depth, CPU cycles and etc. These criteria may be used either jointly or separately to determine whether to use the input data block as a dictionary or not.

Generally, determining whether to use the input data block as the dictionary or not is a balance of a variety of aspects. For more specific details, refer to S2500.
S3200, determining if found blocks are delta-compressed?

If the found similar blocks are not delta-compressed, then go to S3210, otherwise go to S3201.
S3210, delta-compressing the found data blocks.

Specifically, the input data block is used as the dictionary, and the found similar blocks are delta-compressed.

Optionally, the input data block is compressed as unique.

Optionally, the input data block is compressed if needed. Here, the method of compressing the input data block may not be the same with delta-compression.

Optionally, a key-value store is updated with input block features.

Block features like a key-value store and a hash-table could be used for similarity detection. Here, updating the key-value store with the input data block features means adding features of the input data block to a block feature set. The block feature set also contains processed data block features. Features in the block feature set could be used for comparison with future input data block features.
S3220, storing a compression result.

Specifically, the result of delta-compression is stored. The contents of delta-compression have been introduced in S1300. In order to avoid redundancy, details here will not be repeated again and can refer to S1300.
S3201, delta-re-compressing the found blocks.

Before using the input data block as the dictionary to delta-compress the found blocks, found similar blocks are delta-de-compressed by using respective dictionaries and a reference count of those dictionaries is decreased.

Optionally, when the input data block is used as dictionary, the reference count of the input data block is increased by the number of delta-compressed similar blocks.

Optionally, the input data block is compressed as unique.

Optionally, the input data block is compressed if needed. Here, the method of compressing the input data block may not be the same as delta-compression.

Optionally, a key-value store is updated with input block features.

Block features like a key-value store and a hash-table could be used for similarity detection. Here, updating the key-value store with the input data block features means adding features of the input data block to a block feature set. The block feature set also contains processed data block features. Features in the block feature set could be used for comparison with future input data block features.
S3202, optionally, erasing, discarding, deleting or eliminating a previous delta-compression result of the found similar blocks.

Since dictionaries for the delta-compression of the found similar blocks have changed, the previous delta-compression result of the found similar blocks are useless now, and it is helpful to erase the previous delta-compression result of the found similar blocks in terms of storage space.

Optionally, a “zombie” dictionary is discarded.

By eliminating the “zombie” dictionary, it will result in a better CR and a lower recursion depth.

FIG. 4 gives an example for explanation of a “zombie” effect. In this example, we suppose block C and block B are processed data blocks and block A is an input data block, and block B is delta-compressed with block C used as a dictionary. In some possible embodiments, a similarity degree between block B and block A is above a predefined threshold, and block A is not fuzzy equal to block B.

If block A is delta-compressed with block B used as a dictionary, then the compression result is block C (or dictionary C), delta of block B and delta of block A. If block B is delta-compressed with block A (the input data block) used as a dictionary, then the compression result is delta of block B and compressed block A (here, the method of compressing block A may not be the same with delta-compression). By this compression method, block C or dictionary C is not needed anymore to delta-decompress block B, since block B now is compressed with block A used as a dictionary. If block C was previously deleted, but retained in storage as dictionary, then block C could be named as a “zombie” dictionary, and it is helpful to achieve a better CR as well as a lower recursion depth by eliminating the “zombie” dictionary.

It should be mentioned that, when block A is delta-compressed with block B used as a dictionary, delta of block A means a difference between block A and dictionary B (block B).
S3023, storing the result of delta-re-compression with a similarity degree as metadata.

The similarity degree stored in metadata could be used to determine the future input data's compression method.

It should be understood that, in the above method embodiments, sequence numbers of the above processes do not mean orders of execution, and the execution order of each process should be determined by its function and internal logic, and should not be considered as any limitation to the implementation process of the embodiments of the present application.

FIG. 5 is a schematic block diagram of an electronic device 500 according to an embodiment of this application. As shown in FIG. 5, the electronic device 500 includes: an obtaining module 501 and a determining module 502.

The obtaining module 501 is configured to obtain an input data block.

The determining module 502 is configured to compress a target data block with the input data block used as a delta-compression dictionary, where the target data block is at least one of processed data blocks.

The determining module 502 is further configured to determine to use the input data block as the delta-compression dictionary according to reference information to delta-compress the target data blocks, where the reference information is used to evaluate a delta-compression result of the target data block by using the input data block as the delta-compression dictionary.

In case the target data block is delta-compressed, the determining module 502 is further configured to decompress the target data block as a decompression result and compress the decompression result with the input data block used as the delta-compression dictionary as well.

The determining module 502 is further configured to delete a dictionary used previously for delta-compression, where that previous compression dictionary was used to compress the target data block and the previous compression dictionary differs from the input data block.

The determining module 502 is further configured to delete the previous compression result of the target data block, where the previous compression result is corresponding to the decompression result.

Optionally, in some embodiments, the reference information includes one or more of a compression recursion depth, a compression ratio and CPU cycles.

Optionally, in some embodiments, a similarity degree between the target data block and the input data block is within a threshold range.

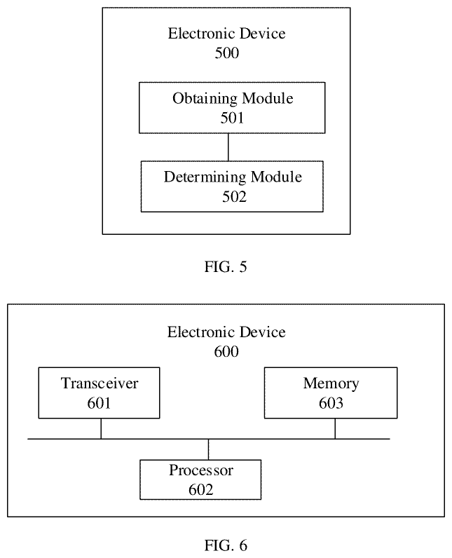

FIG. 6 shows a schematic block diagram of an electronic device 600 according to an embodiment of this application. As shown in FIG. 6, the electronic device 600 may include a transceiver 601, a processor 602, and a memory 603. The memory 603 may be configured to store codes, instructions, and the like executed by the processor 602.

It should be understood that the processor 602 may be an integrated circuit chip and has a signal processing capability. In an implementation process, steps of the foregoing method embodiments may be completed by using a hardware integrated logic circuit in the processor, or by using instructions in a form of software. The processor may be a general purpose processor, a digital signal processor (Digital Signal Processor, DSP), an application-specific integrated circuit (Application Specific Integrated Circuit, ASIC), a field programmable gate array (Field Programmable Gate Array, FPGA) or another programmable logic device, a discrete gate or transistor logic device, or a discrete hardware component. The processor may implement or perform the methods, the steps, and the logical block diagrams that are disclosed in the embodiments of the present invention. The general purpose processor may be a microprocessor, or the processor may be any conventional processor or the like. The steps of the methods disclosed with reference to the embodiments of the present invention may be directly performed and completed by a hardware decoding processor, or may be performed and completed by using a combination of hardware in the decoding processor and a software module. The software module may be located in a mature storage medium in the art, such as a random access memory, a flash memory, a read-only memory, a programmable read-only memory, an electrically erasable programmable memory, or a register. The storage medium is located in the memory, and the processor reads information in the memory and completes the steps of the foregoing methods in combination with hardware in the processor.

It may be understood that the memory 603 in the embodiments of the present invention may be a volatile memory or a nonvolatile memory, or may include both a volatile memory and a nonvolatile memory. The nonvolatile memory may be a read-only memory (Read-Only Memory, ROM), a programmable read-only memory (Programmable ROM, PROM), an erasable programmable read-only memory (Erasable PROM, EPROM), an electrically erasable programmable read-only memory (Electrically EPROM, EEPROM), or a flash memory. The volatile memory may be a random access memory (Random Access Memory, RAM) and is used as an external cache. By way of example rather than limitation, many forms of RAMs may be used, and are, for example, a static random access memory (Static RAM, SRAM), a dynamic random access memory (Dynamic RAM, DRAM), a synchronous dynamic random access memory (Synchronous DRAM, SDRAM), a double data rate synchronous dynamic random access memory (Double Data Rate SDRAM, DDR SDRAM), an enhanced synchronous dynamic random access memory (Enhanced SDRAM, ESDRAM), a synchronous link dynamic random access memory (Synchronous link DRAM, SLDRAM), and a direct rambus random access memory (Direct Rambus RAM, DR RAM).

It should be noted that the memory in the systems and the methods described in this specification includes but is not limited to these memories and may be a memory of any other appropriate type.

An embodiment of this application further provides a system chip, where the system chip includes an input/output interface, at least one processor, at least one memory, and a bus. The at least one memory is configured to store instructions, and the at least one processor is configured to invoke the instructions of the at least one memory to perform operations performed in the methods in the foregoing embodiments.

An embodiment of this application further provides a computer storage medium, where the computer storage medium may store a program instruction for performing the steps performed in the foregoing methods.

Optionally, the storage medium may be specifically the memory 603.

An embodiment of this application further provides a computer program product, where when the computer program product is run on an electronic device, the electronic device is enabled to perform the steps performed by the electronic device 600 in the foregoing methods.

A person of ordinary skill in the art may be aware that, in combination with the examples described in the embodiments disclosed in this specification, units and algorithm steps can be implemented by electronic hardware or a combination of computer software and electronic hardware. Whether the functions are performed by hardware or software depends on particular applications and design constraints of the technical solutions. A person skilled in the art may use different methods to implement the described functions for each particular application, but it should not be considered that the implementation goes beyond the scope of this application.

It may be clearly understood by a person skilled in the art that, for the purpose of convenient and brief description, for a detailed working process of the foregoing system, apparatus, and unit, refer to a corresponding process in the foregoing method embodiment. Details are not described herein again.

In the several embodiments provided in this application, it should be understood that the disclosed system, apparatus, and method may be implemented in other manners. For example, the described apparatus embodiment is merely an example. For example, the unit division is merely logical function division and may be other division in actual implementation. For example, a plurality of units or components may be combined or integrated into another system, or some features may be ignored or not performed. In addition, the displayed or discussed mutual couplings or direct couplings or communication connections may be implemented through some interfaces. The indirect couplings or communication connections between the apparatuses or units may be implemented in electronic, mechanical, or other forms.

The units described as separate parts may be or may not be physically separate, and parts displayed as units may be or may not be physical units, may be located in one position, or may be distributed on a plurality of network units. Some or all of the units may be selected based on actual requirements to achieve the objectives of the solutions of the embodiments.

In addition, functional units in the embodiments of this application may be integrated into one processing unit, or each of the units may exist alone physically, or two or more units are integrated into one unit.

When the functions are implemented in a form of a software functional unit and sold or used as an independent product, the functions may be stored in a computer readable storage medium. Based on such an understanding, the technical solutions in this application essentially, or the part contributing to the prior art, or some of the technical solutions may be implemented in a form of a software product. The computer software product is stored in a storage medium, and includes several instructions for instructing a computer device (which may be a personal computer, a server, a network device, or the like) to perform all or some of the steps of the methods described in the embodiments of this application. The foregoing storage medium includes: any medium that can store program code, such as a USB flash drive, a removable hard disk, a read-only memory (ROM), a random access memory (RAM), a magnetic disk, or an optical disc.

The foregoing descriptions are merely specific implementations of this application but are not intended to limit the protection scope of this application. Any variation or replacement readily figured out by a person skilled in the art within the technical scope disclosed in this application shall fall within the protection scope of this application. Therefore, the protection scope of this application shall be subject to the protection scope of the claims.

1.-23. (canceled)

24. A method, comprising:
obtaining an input data block; and
processing the input data block according to one of the following methods:
delta-compressing one or more target data blocks by using the input data block as a compression dictionary, wherein each target data block is one of processed data blocks; or
delta-compressing the input data block by using one of processed data blocks as a compression dictionary.

25. The method according to claim 24, further comprising:
before processing the input data block, determining to use the input data block as the compression dictionary, according to reference information, to delta-compress the one or more target data blocks, wherein the reference information is used to evaluate compression or decompression costs of the one or more target data blocks by using the input data block as the compression dictionary, and
incrementing a reference count of the input data block by a number of the one or more target data blocks.

26. The method according to claim 25, wherein the reference information comprises one or more of a compression ratio, central processing unit (CPU) cycles spent for delta-compression or delta-decompression, or latencies of compression or decompression due to delta-compression recursion depth.

27. The method according to claim 24, wherein in a case that the one or more target data blocks are delta-compressed, delta-compressing the one or more target data blocks by using the input data block as the compression dictionary comprises:
decompressing each of the one or more target data blocks as a decompression result;
compressing the decompression result by using the input data block as the compression dictionary, and
incrementing a reference count of the input data block by 1.

28. The method according to claim 27, further comprising:
decrementing a reference count of a previous compression dictionary, wherein the previous compression dictionary is used to compress the one or more target data blocks, and the previous compression dictionary differs from the input data block.

29. The method according to claim 28, further comprising:
deleting the previous compression dictionary in response to the reference count being 0.

30. The method according to claim 27, further comprising:
deleting a previous compression result of each of the one or more target data blocks, wherein the previous compression result is corresponding to the decompression result.

31. The method according to claim 27, further comprising:
checking whether the one or more target data blocks are delta-compressed.

32. The method according to claim 24, further comprising:
storing a similarity degree between each of the one or more target data blocks and the input data block.

33. The method according to claim 25, further comprising:
before determining to use the input data block as the compression dictionary, according to the reference information, to delta-compress the one or more target data blocks, verifying that a similarity degree between each of the one or more target data blocks and the input data block is within a threshold range.

34. An electronic device, comprising:
at least one processor; and
a memory storing instructions that are executable by the at least one processor, wherein execution of the instructions enables the electronic device to:
obtain an input data block; and
the input data block according to one of the following:
delta-compress one or more target data blocks by using the input data block as a compression dictionary, wherein each of the one or more target data blocks is one of processed data blocks; or
delta-compress the input data block by using one of processed data blocks as a compression dictionary.

35. The electronic device according to claim 34, wherein execution of the instructions enables the electronic device to:
determine to use the input data block as the compression dictionary, according to reference information, to delta-compress the one or more target data blocks, wherein the reference information is used to evaluate compression or decompression costs of the one or more target data blocks by using the input data block as the compression dictionary; and
increment a reference count of the input data block by a number of the one or more target data blocks.

36. The electronic device according to claim 35, wherein the reference information comprises one or more of a compression ratio, central processing unit (CPU) cycles spent for delta-compression and delta-decompression, or latencies of compression and decompression due to delta-compression recursion depth.

37. The electronic device according to claim 34, wherein execution of the instructions enables the electronic device to:
in a case that the target data blocks are delta-compressed, decompress each of the one or more target data blocks as a decompression result;
compress the decompression result by using the input data block as the compression dictionary, and
increment a reference count of the input data block by 1.

38. The electronic device according to claim 37, wherein execution of the instructions enables the electronic device to:
decrement a reference count of a previous compression dictionary, wherein the previous compression dictionary is used to compress the one or more target data blocks, and the previous compression dictionary differs from the input data block.

39. The electronic device according to claim 38, wherein execution of the instructions enables the electronic device to:
delete the previous compression dictionary in response to the reference count being 0.

40. The electronic device according to claim 37, wherein execution of the instructions enables the electronic device to:
delete a previous compression result of each of the one or more target data blocks, wherein the previous compression result is corresponding to the decompression result.

41. The electronic device according to claim 37, wherein execution of the instructions enables the electronic device to:
check whether the one or more target data blocks are delta-compressed.

42. The electronic device according to claim 34, wherein execution of the instructions enables the electronic device to:
store a similarity degree between each of the one or more target data blocks and the input data block.

43. The electronic device according to claim 35, wherein execution of the instructions enables the electronic device to:
before determining to use the input data block as the compression dictionary, according to the reference information, to delta-compress the one or more target data blocks, verify that a similarity degree between each of the one or more target data blocks and the input data block is within a threshold range.
